(19) United States
(12) Patent Application Publication
(10) Pub. No.: US 2008/0057734 A1
(43) Pub. Date: Mar. 6, 2008

(54) Apparatus for fabricating a semiconductor device and method of fabricating a semiconductor device using the same

(75) Inventor: Dae Young Kim, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/895,325

(22) Filed: Aug. 24, 2007

(30) Foreign Application Priority Data
Aug. 31, 2006 (KR) 10-2006-0083475

(51) Int. Cl. H01L 21/31; C23C 16/00

(52) U.S. Cl. 438/762; 118/719; 257/E21.24

(57) ABSTRACT

An apparatus for fabricating layers on a semiconductor device comprises a first chamber in which a pad oxide layer and a pad nitride layer are successively formed, and a second chamber in which a pad insulating layer is formed and heated.

The present application claims priority under 35 U.S.C. 119 and 35 U.S.C. 365 to Korean Patent Application No. 10-2006-0083475 (filed on Aug. 31, 2006), which is hereby incorporated by reference in its entirety.

### BACKGROUND

Embodiments of the invention relate to an apparatus for fabricating layers on a semiconductor device and a method of fabricating a semiconductor device using the same.

In order to realize shallow trench isolation (STI) in a complementary metal oxide semiconductor (CMOS) structure, a multilayer hard mask can be formed by various processes such as forming a pad oxide layer, forming a pad nitride layer, forming a pad insulating layer, and heat-treating a pad insulating layer. These steps are generally separated into unit processes, each of which is a furnace process that may consume a relatively long process time. Thus, it can take quite a long time to form the pad or hard mask.

A related apparatus for fabricating a semiconductor device includes equipment for forming the pad oxide layer, equipment for forming the pad nitride layer, equipment for forming the pad insulating layer, and equipment for heat-treating the pad insulating layer. The related apparatus for fabricating a semiconductor device has difficulty in configuring these pieces of equipment, and increases a process time, because it has to sequentially load/unload a substrate on/from the various pieces of equipment for the separate processes.

Embodiments of the invention provide an apparatus for fabricating layers on a semiconductor device and a fabricating method of the semiconductor device using the same, capable of reducing the number of processes and reducing the process time.

One embodiment provides an apparatus for fabricating layers on a semiconductor device. The apparatus comprises a first chamber adapted to form a pad oxide layer and a pad nitride layer on a semiconductor substrate, and a second chamber adapted to form and heat a pad insulating layer.

Another embodiment provides a method of fabricating layers on a semiconductor device. The method comprises sequentially forming a pad oxide layer on a semiconductor substrate and forming a pad nitride layer on the pad oxide layer in a first chamber, and sequentially forming a pad insulating layer and heating the pad insulating layer in a second chamber.

### BRIEF DESCRIPTION OF THE DRAWINGS

FIG. 1 is a view for explaining a first chamber in an apparatus of fabricating a semiconductor device according to an embodiment of the invention;

FIG. 2 is a view for explaining a second chamber in an apparatus of fabricating a semiconductor device according to an embodiment of the invention; and

FIG. 3 is a flowchart illustrating an exemplary method of fabricating a semiconductor device using an exemplary apparatus according to exemplary embodiments of the invention.

### DETAILED DESCRIPTION OF THE EMBODIMENTS

In the description of the embodiment, it will be understood that, when a layer (or film), a region, a pattern, or a structure is referred to as being “on/above” or “under/below” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

Hereinafter, exemplary embodiments of the invention will be described in detail with reference to the accompanying drawings.

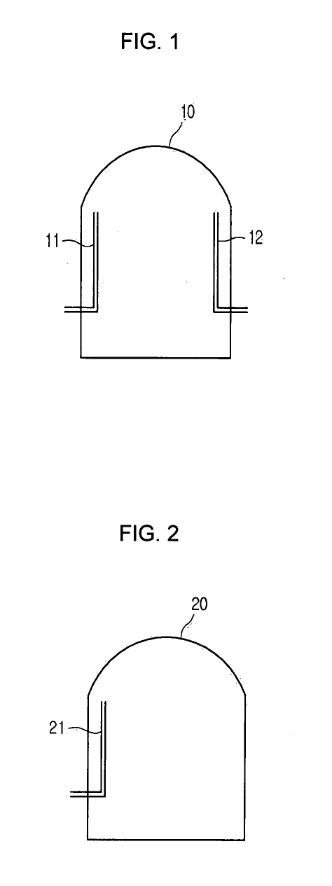

An apparatus for fabricating layers on a semiconductor device according to embodiments of the invention comprises first and second chambers. FIG. 1 is a view for explaining a first chamber in an exemplary apparatus, and FIG. 2 is a view for explaining a second chamber in an exemplary apparatus.

The apparatus for fabricating a semiconductor device according to embodiments of the invention has a first chamber 10 (see FIG. 1) in which a process of forming a pad oxide layer and a pad nitride layer is carried out, and the second chamber 20 in which a process of forming a pad insulating layer and heat-treating the pad insulating layer is carried out. In other words, the process of forming a pad oxide layer as well as the process of forming a pad nitride layer can be performed in the first chamber 10. Further, the process of forming a pad insulating layer as well as the process of heat-treating the pad insulating layer can be performed in the second chamber 20.

In the present apparatus, as illustrated in FIG. 1, the first chamber 10 includes a first gas pipe 11 through which gas for forming the pad oxide layer is supplied, and a second gas pipe 12 through which gas for forming the pad nitride layer is supplied. The gas for forming the pad oxide layer may comprise an oxygen source gas, such as dioxygen, ozone, or tetraethoxysilane (TEOS). The gas for forming the pad nitride layer may comprise a nitrogen source gas, such as dinitrogen, ammonia or hydrazine, and optionally a silicon source gas such as a chlorosilane (e.g., a compound of the formula SiₓH_{y}Cl_{z}, where x is 1-4 [preferably 1], z is from x to 2×, and [y+z]=2x+2). For example, dioxygen gas can be supplied through the first gas pipe 11. Nitrogen, ammonia, and/or dichlorosilane (DCS) gas can be supplied through the second gas pipe 12. Alternatively, a gas such as an aminosilane can be supplied through the second gas pipe 12.

Further, in the present apparatus, as illustrated in FIG. 2, the second chamber 20 includes a third gas pipe 21 through which gas for forming the pad insulating layer is supplied, and a heat supply unit for performing the heat treatment. The gas for forming the pad insulating layer may comprise one or more oxygen and silicon source gasses, such as tetraethoxysilane (TEOS), or mixtures of (1) a silane of the formula SiₓH_{y}Cl_{z} above, but where z can (and preferably is) 0, and (2) an oxygen source gas such as dioxygen or ozone. For example, tetraethoxysilane (TEOS) gas can be supplied through the third gas pipe 21, and the heat supply unit can be (or comprise) an electric furnace.

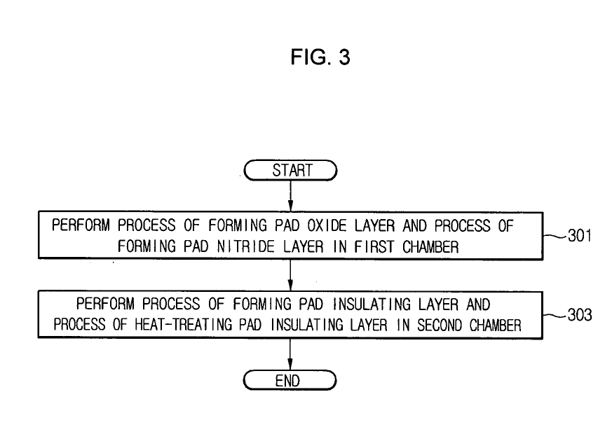

Now, a method of fabricating a semiconductor device using the apparatus having this configuration will be described in brief with reference to FIG. 3. FIG. 3 is a flowchart illustrating an exemplary method of fabricating layers on a semiconductor device using an apparatus for fabricating such layers on the semiconductor device.

In the present method of fabricating layers on a semiconductor device, a process of forming a pad oxide layer and a process of forming a pad nitride layer are sequentially carried out in the first chamber (s301). A process of forming a pad insulating layer and a process of heat-treating the pad insulating layer are sequentially carried out in the second chamber 20 (s303).

In step 301, the process of forming the pad oxide layer is carried out, for instance, by supplying oxygen gas through the first gas pipe 11 of the first chamber 10. Further, in step 301, the process of forming the pad nitride layer is carried out, for instance, by supplying nitrogen, ammonia, and/or dichlorosilane (DCS) gas through the second gas pipe 12 of the first chamber 10. In addition, in step 301, after the pad oxide layer is formed, the nitrogen gas may be introduced to remove the oxygen gas from the first chamber 10, and then the pad nitride layer is formed.

Meanwhile, in step 303, the process of forming the pad insulating layer is carried out, for instance, by supplying tetraethoxysilane (TEOS) gas through the third gas pipe 21 of the second chamber 20. Further, in step 303, the heat treatment can be realized, for instance, by an electric furnace. At this time, the heat treatment can be performed in the state in which a nitrogen source gas is introduced, and heating can be performed sufficiently to increase the density of the pad insulating layer. Such heating may be performed at a temperature of from 400 to 1100° C., 550 to 1000° C., 600 to 900° C., or any range of values therein, for a length of time sufficient to densify the pad insulating layer to a predetermined extent.

In the present method of fabricating layers on a semiconductor device, after the pad insulating layer is formed in the second chamber 20, the heat treatment is performed on the pad insulating layer at a relatively high temperature. In other words, the apparatus and method for fabricating layers on a semiconductor device according to exemplary embodiments can perform the processes that were individually performed in four separate chambers in the related art, in two chambers. Such chambers (at least in the present invention) may be included in a multi-chamber furnace apparatus, further comprising a conveyor and/or a conveying chamber (to which the first and second chambers are communicatively attached) for transporting the semiconductor substrates. Thus, the number of processes for forming the pad can be reduced. Two unit processes, rather than four unit processes are performed, so that the process time can be reduced.

As described above, the apparatus and method for fabricating layers on a semiconductor device according to exemplary embodiments has an advantage in that the number of processes can be reduced, and thus the process time can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus, comprising:
a first chamber adapted to form a pad oxide layer and a pad nitride layer on a semiconductor substrate; and
a second chamber adapted to form and heat a pad insulating layer.

2. The apparatus as claimed in claim 1, wherein the first chamber includes a first gas pipe adapted to supply a first gas for forming the pad oxide layer, and a second gas pipe adapted to supply a second gas for forming the pad nitride layer.

3. The apparatus as claimed in claim 2, wherein the first gas pipe supplies an oxygen source gas.

4. The apparatus as claimed in claim 3, wherein the oxygen source gas comprises dioxygen.

5. The apparatus as claimed in claim 2, wherein the second gas pipe supplies at least one of a nitrogen source gas and a silicon source gas.

6. The apparatus as claimed in claim 5, wherein the nitrogen source gas comprises dinitrogen, ammonia, or hydrazine, and the silicon source gas comprises a chlorosilane.

7. The apparatus as claimed in claim 1, wherein the second chamber includes a third gas pipe adapted to supply a third gas for forming the pad insulating layer, and a heat supply unit for heating the substrate.

8. The apparatus as claimed in claim 7, wherein the third gas pipe supplies one or more silicon and oxygen source gas(ses).

9. The apparatus as claimed in claim 8, wherein the silicon and oxygen source gas(ses) comprise tetraethoxysilane (TEOS).

10. The apparatus as claimed in claim 7, wherein the heat supply unit includes an electric furnace.

11. A method of fabricating multiple layers on a semiconductor substrate, the method comprising:
sequentially forming a pad oxide layer and a pad nitride layer on the semiconductor substrate in a first chamber; and
sequentially forming a pad insulating layer on the pad nitride layer and heating the pad insulating layer in a second chamber.

12. The method as claimed in claim 11, wherein:
the first chamber includes a first gas pipe adapted to supply a first gas for forming the pad oxide layer, and a second gas pipe adapted to supply a second gas for forming the pad nitride layer.

13. The method as claimed in claim 11, wherein the first gas comprises an oxygen source gas, and the second gas comprises a nitrogen source gas.

14. The method as claimed in claim 13, wherein:
after the pad oxide layer is formed, the method further comprises introducing the nitrogen source gas under conditions sufficient to remove the oxygen source gas from the first chamber, and then forming the pad nitride layer.

15. The method as claimed in claim 13, wherein the oxygen source gas comprises dioxygen.

16. The method as claimed in claim 13, wherein the nitrogen source gas comprises dinitrogen, ammonia, or hydrazine.

17. The method as claimed in claim 11, wherein:
the second chamber includes a third gas pipe adapted to supply a third gas for forming the pad insulating layer, and a heat supply unit for heating the substrate.

18. The method as claimed in claim 11, wherein:
after the pad insulating layer is formed, the method further comprises heating treatment the pad insulating layer.

19. The method as claimed in claim 17, wherein the third gas pipe supplies one or more silicon and oxygen source gas(ses).

20. The method as claimed in claim 17, wherein the heat supply unit includes an electric furnace.
